(19) United States
(12) Patent Application Publication
(10) Pub. No.: US 2022/0270942 A1
(43) Pub. Date: Aug. 25, 2022

(54) FLIP CHIP SEMICONDUCTOR PACKAGE WITH A LEADFRAME TO ENHANCE PACKAGE MECHANICAL STABILITY AND HEAT DISSIPATION

(71) Applicant: UTAC Headquarters Pte. Ltd., Singapore (SG)

(72) Inventors: Nataporn Charusabha, Bangkok (TH); Kunakorn Kaoson, Bangkok (TH); Saravuth Sirinorakul, Bangkok (TH); Sukhontip Jaikongkaew, Bangkok (TH); Il Kwon Shim, Singapore (SG)

(21) Appl. No.: 17/680,308

(22) Filed: Feb. 25, 2022

Related U.S. Application Data
(60) Provisional application No. 63/153,925, filed on Feb. 25, 2021.

(51) Int. Cl. H01L 23/24; H01L 23/00; H01L 23/367; H01L 21/56

(52) U.S. Cl. CPC H01L 23/24; H01L 23/562; H01L 23/367; H01L 21/568; H01L 21/561; H01L 24/32; H01L 2224/32245; H01L 2224/29139; H01L 24/29

(57) ABSTRACT

A flip chip package is disclosed. The package includes a leadframe surrounding a flip chip. The leadframe and flip chip are encapsulated by a mold compound. The leadframe provides package support to enhance the mechanical stability of the package. In some cases, a heat dissipating structure is disposed on top of the package, connecting the flip chip to enhance heat dissipation.

### CROSS-REFERENCE TO RELATED APPLICATION

This application claims the benefit of U.S. Provisional Application Ser. No. 63/153,925, filed on Feb. 25, 2021, which is herein incorporated by reference in its entirety for all purposes.

### FIELD OF THE INVENTION

The present invention generally relates to a semiconductor package. More specifically, the present invention is directed to a flip chip semiconductor package with a leadframe.

### BACKGROUND

The recent rapid dissemination of smartphones and other mobile and wearable electronic terminals drives the demand for products that are more compact and power-efficient. To meet these requirements, smaller and smaller IC packages are developed. For example, flip chips packages are employed to achieve small package sizes. An important aspect of packages is mechanical stability. For example, the package needs to be strong enough to withstand processing and handling. In addition, depending on the application, heat may be required to be dissipated to maintain the package within an operating temperature range.

The present disclosure is directed to flip chip packages with improved mechanical stability and heat dissipation.

### SUMMARY

A semiconductor package is disclosed. In one embodiment, the semiconductor package includes a flip chip having opposing active and inactive chip surfaces. The active chip surface includes chip pads. The package also includes a leadframe surrounding the flip chip. The leadframe includes top and bottom leadframe surfaces. The bottom leadframe surface includes leadframe pads. The package further includes an encapsulant having opposing top and bottom encapsulant surfaces. The encapsulant encapsulates the leadframe and the flip chip. The bottom encapsulant surface exposes the leadframe pads and chip pads. The package also includes leadframe contacts coupled to the leadframe pads and chip contacts coupled to the chip pads. The leadframe contacts and chip contacts protrude from the bottom mold compound surface and form package contacts of the semiconductor package.

In another embodiment, a method for forming a semiconductor package is disclosed. The method includes providing a leadframe with top and bottom leadframe surfaces. The bottom leadframe surface includes leadframe pads. The method also includes attaching the bottom leadframe surface to a support adhesive tape, and providing a flip chip having opposing active and inactive chip surfaces. The active chip surface includes chip pads. The method further includes attaching the chip pads of the flip chip to the support adhesive tape within a chip region in a central portion of the leadframe; encapsulating the leadframe with the flip chip with an encapsulant; removing the support tape to expose bottom leadframe pad surfaces of the leadframe pads and bottom chip pad surfaces of the chip pads; and forming leadframe contacts on the bottom leadframe pad surfaces and chip contacts on the bottom chip pad surfaces.

In yet another embodiment, a method for forming a semiconductor package includes providing a leadframe strip with a plurality of leadframes. The leadframe strip includes top and bottom leadframe strip surfaces. The bottom leadframe strip surface includes leadframe pads of the plurality of leadframes. The method further includes attaching the bottom leadframe strip surface to a support adhesive tape. The method also includes providing flip chips having opposing active and inactive chip surfaces. The active chip surface of the flip chips includes chip pads. The method further includes attaching the chip pads of the plurality of flip chips to the support adhesive tape within chip regions of the leadframes. A chip region of a leadframe is a central portion of the leadframe. The method also includes encapsulating the leadframe strip with the flip chips with an encapsulant; removing the support tape to expose bottom leadframe pad surfaces of the leadframe pads and bottom chip pad surfaces of the chip pads; forming leadframe contacts on the bottom leadframe pad surfaces and chip contacts on the bottom chip pad surfaces; and singulating the leadframe strip into individual packages.

These and other advantages and features of the embodiments herein disclosed, will become apparent through reference to the following description and the accompanying drawings. Furthermore, it is to be understood that the features of the various embodiments described herein are not mutually exclusive and can exist in various combinations and permutations.

### BRIEF DESCRIPTION OF THE DRAWINGS

In the drawings, like reference characters generally refer to the same parts throughout the different views. Also, the drawings are not necessarily to scale, emphasis instead generally being placed upon illustrating the principles of the invention. In the following description, various embodiments of the present invention are described with reference to the following drawings, in which:

FIGS. 1a-1b show cross-sectional and top views of an embodiment of a semiconductor package;

FIGS. 1c-1d show cross-sectional and top views of another embodiment of a semiconductor package;

FIGS. 2a-2b show cross-sectional and top views of an embodiment of a semiconductor package with a heat sink;

FIGS. 2c-2d show cross-sectional and top views of another embodiment of a semiconductor package with a heat sink;

FIGS. 3a-3b show cross-sectional and top views of another embodiment of a semiconductor package with a heat dissipation structure;

FIGS. 3c-3d show cross-sectional and top views of another embodiment of a semiconductor package with a heat dissipation structure;

FIGS. 4a-4b show embodiments of a leadframe;

FIGS. 5a-5f show cross-sectional views depicting an embodiment of a process flow for forming a semiconductor package;

FIGS. 6a-6e show cross-sectional views depicting another embodiment of a process flow for forming a semiconductor package; and

FIGS. 7a-7d show cross-sectional views depicting yet another embodiment of a process flow for forming a semiconductor package.

### DETAILED DESCRIPTION

Embodiments relate to flip chip semiconductor packages and methods for forming thereof. More specifically, embodiments relate to flip chip semiconductor packages with improved mechanical stability. In other embodiments, they relate to flip chip packages with improved mechanical stability and heat dissipation performance.

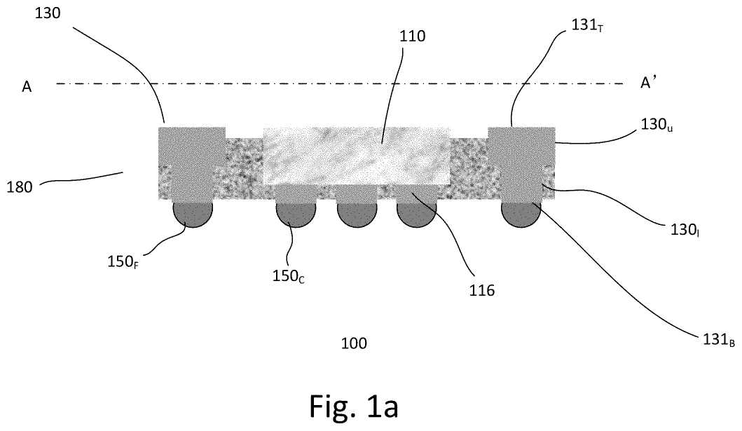

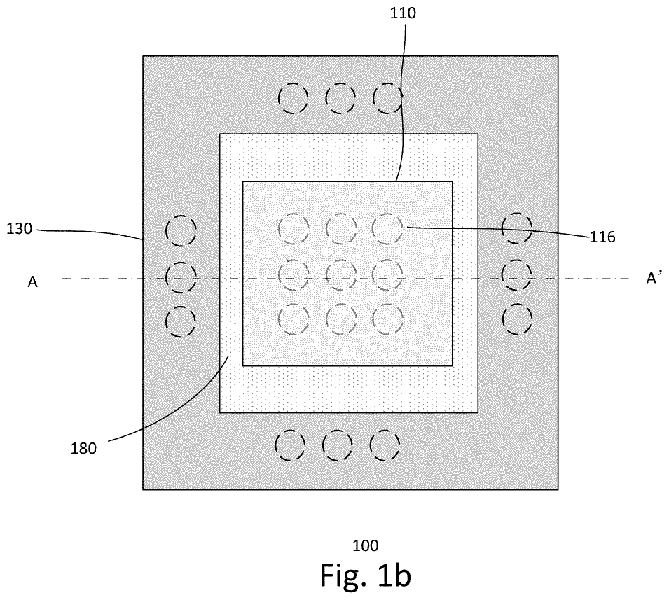

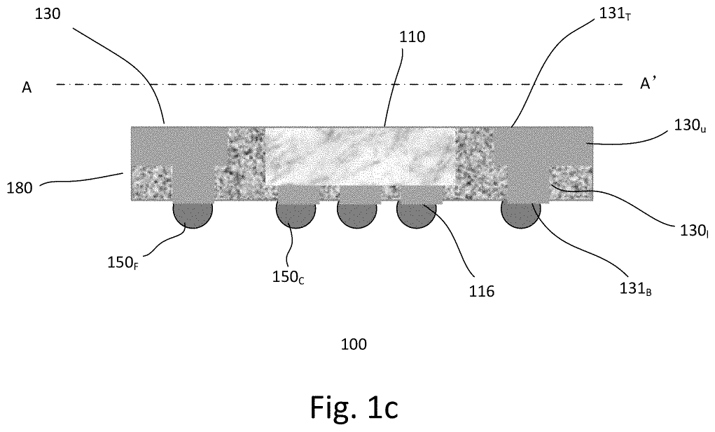

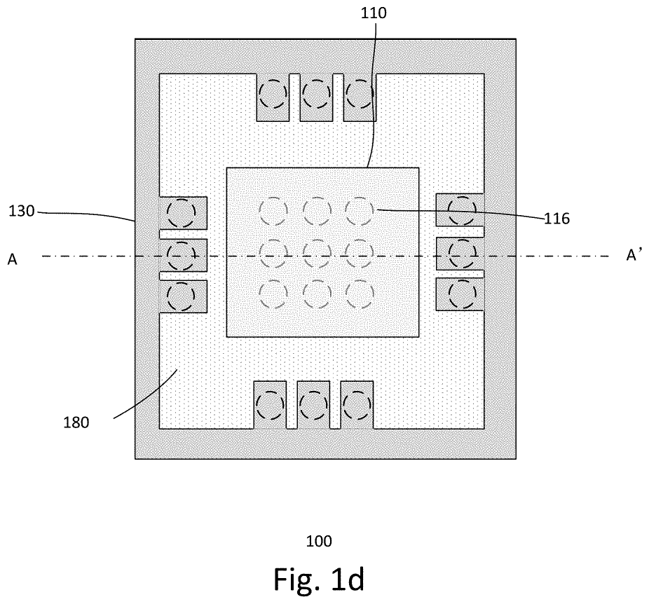

FIGS. 1a-1b show cross-sectional and top views of an embodiment of a semiconductor package 100. FIGS. 1c-1d show cross-sectional and top views of another embodiment of a semiconductor package 100. The cross-sectional views are along A-A′ of the top views.

As shown, the semiconductor package includes a flip chip 110. The flip chip includes active and inactive major surfaces. The active and inactive surfaces, for example, are horizontal planar surfaces. In one embodiment, the flip chip is a rectangular-shaped flip chip with four side surfaces. The side surfaces may be vertical planar surfaces which are orthogonal to the active and inactive horizontal major surfaces. Other configurations of the surfaces may also be useful. The active surface includes chip pads 116. The chip pads are conductive chip pads, such as aluminum or aluminum alloy pads. Other types of conductive pads may also be useful. The chip pads are coupled to circuit components formed on a substrate through backend interconnect layers. The chip pads may be configured in a grid pattern on the active surface of the flip chip. Other configurations of the chip pads may also be useful.

The package includes a leadframe 130 surrounding the flip chip. For example, the flip chip is disposed within a chip region of the leadframe. In one embodiment, the leadframe includes an upper leadframe portion 130ᵤ and a lower leadframe portion 130_{L}. The top surface of the upper leadframe portion forms a top leadframe surface 131_{T} and a bottom surface of the lower leadframe portion forms a bottom leadframe surface 131_{B}. In one embodiment, the upper leadframe portion forms a ring structure surrounding the flip chip. In one embodiment, the ring structure is a rectangular-shaped ring structure surrounding the flip chip. In one embodiment, the ring structure is a continuous ring structure, such as a continuous rectangular-shaped ring structure. Providing a non-continuous ring structure may also be useful. As for the lower leadframe portion, it includes leadframe pads. The leadframe pads are, for example, distinct posts extending from the ring structure. In one embodiment, the leadframe pads have a bottom surface area which is the same as the flip chip pads.

In another embodiment, as shown in FIGS. 1c-1d, the upper leadframe portion 130ᵤ includes extensions extending inwardly into the chip region of the leadframe. The extensions, for example, are fingerlike extensions to accommodate the leadframe pads. The extensions improve mechanical stability as well as heat dissipation.

In one embodiment, the leadframe is a conductive leadframe. Preferably, the leadframe is a thermal conductive leadframe, such as a copper (Cu) or copper alloy leadframe. Other types of conductive or thermal conductive materials, such as aluminum (Al), nickel (Ni), silver (Ag), gold (Au) or alloys thereof may also be used to form the lead frame. The leadframe, for example, may be formed by stamping. Other techniques for forming the leadframe, such as etching, may also be useful.

In one embodiment, an encapsulant 180 encapsulates the flip chip and leadframe. The encapsulant, for example, may be a mold compound. The encapsulant may be formed by, for example, transfer molding, compression molding or other techniques. Other types or techniques for forming the encapsulant may also be useful.

As shown, the encapsulant includes opposing top and bottom major encapsulant surfaces and side encapsulant surfaces. The surfaces, for example, are planar surfaces. For example, the top and bottom major encapsulant surfaces are horizontal planar encapsulant surfaces and the side encapsulant surfaces are vertical planar encapsulant surfaces which are orthogonal to the horizontal planar encapsulant surfaces. Other configurations of the encapsulant surfaces may also be useful.

In one embodiment, the upper portion of the leadframe is coextensive with the sides of the package. For example, sides of the upper portion of the leadframe are exposed. Since the pads in the lower portion of the leadframe are recessed from the sides, they are covered by the encapsulant. For example, the side encapsulant surfaces covering the pads in the lower portion of the leadframe are coextensive or aligned with the side surfaces of the upper portion of the leadrame.

In one embodiment, the bottom encapsulant surface is co-planar with the bottom leadframe and bottom chip pad surfaces. For example, the bottom leadframe and bottom chip pad surfaces are exposed by the encapsulant. As for the top encapsulant surface, in one embodiment, it is recessed slightly below the top chip surface and the top leadframe surface. For example, the top encapsulant surface may be recessed by about less than 5 um below the top chip surface and the top leadframe surface. Recessing the top encapsulant surface by other amounts may also be useful. By slightly exposing the flip chip and leadframe, the leadframe serves as an indirect heat dissipation structure. For example, heat from the flip chip is transferred to the leadframe indirectly through the mold compound. Thus, indirect heat dissipation can be achieved.

In other embodiments, the surfaces of the encapsulant, leadframe, and chip may have other configurations. For example, the top encapsulant surface may be coplanar with the top chip surface and top leadframe surface. In such cases, the top leadframe and chip surfaces are exposed. In some other embodiments, the top encapsulant surface may cover the chip and leadframe. For example, the top encapsulant surface may slightly cover the chip and leadframe. The top encapsulant surface may cover the chip and leadframe by less than about 5 um.

In one embodiment, leadframe contacts 150_{F} are disposed on the exposed leadframe pad surfaces; chip contacts 150_{C} are disposed on exposed chip pad surfaces. The contacts, for example, are solder ball or bump contacts. Other types of contacts may also be useful. The contacts serve as package contacts. For example, the package contacts may be coupled to a circuit board with other ICs and components. In one embodiment, the leadframe contacts and chip contacts have the same volume.

In one embodiment, the leadframe is not connected to the chip. For example, the leadframe contacts are non-functional contacts of the package. For example, the leadframe contacts do not transmit electrical signals to the flip chip. As described, the leadframe is thermally conductive. The leadframe serves as a heat dissipation structure. For example, the leadframe dissipates heat from the flip chip which is transferred via the encapsulant. The encapsulant serves as an intermedium to transfer heat from the flip chip to the leadframe. The leadframe, in one embodiment, serves to provide package protection. For example, the leadframe enhances the mechanical stability of the package. In one embodiment, the leadframe improves mechanical stability of and dissipates heat from the package.

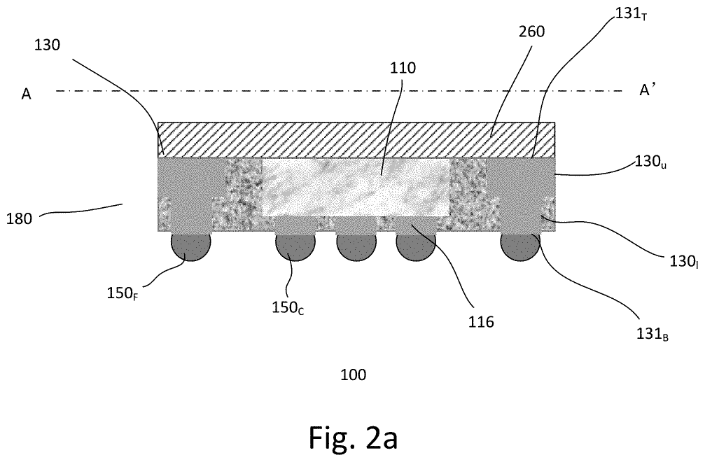

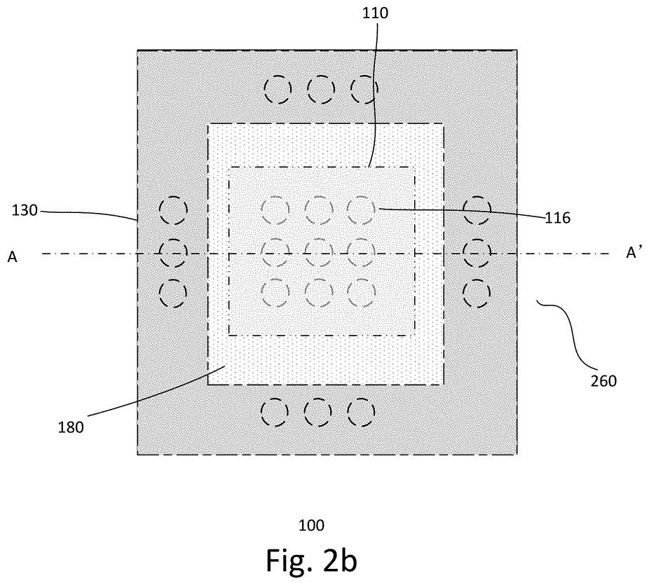

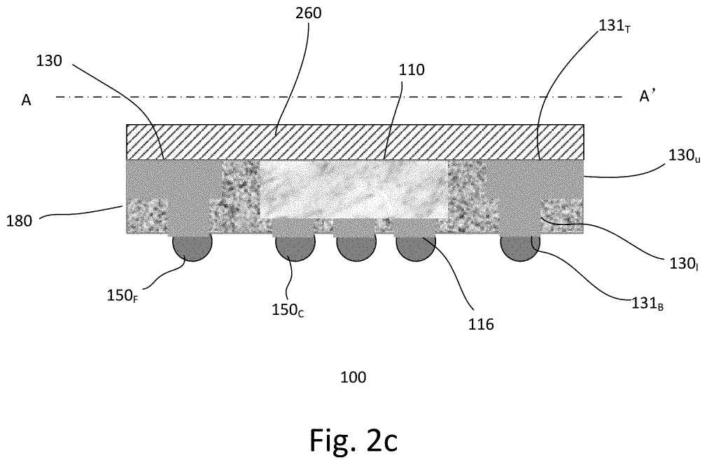

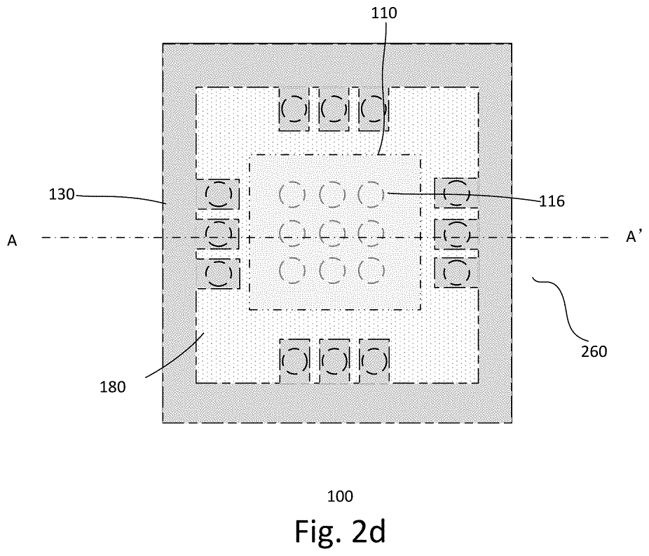

FIGS. 2a-2b show cross-sectional and top views of an embodiment of a semiconductor package 100. FIGS. 2c-2d show cross-sectional and top views of another embodiment of a semiconductor package 100. The cross-sectional views are along A-A′ of the top views. The semiconductor packages are similar to the semiconductor packages described in FIGS. 1a-1d. As such, common elements may not be described or described in detail.

As shown, the semiconductor package includes a flip chip 110. The flip chip includes an active surface with chip pads 116. The package includes a leadframe 130 surrounding the flip chip. In one embodiment, the leadframe includes an upper leadframe portion 130ᵤ and a lower leadframe portion 130ₗ. The upper leadframe portion forms a ring structure surrounding the flip chip. The lower leadframe portion includes leadframe pads. The leadframe pads are, for example, distinct posts extending from the ring structure. In one embodiment, the leadframe pads have a bottom surface area which is the same as the flip chip pads. In some embodiments, as shown in FIGS. 2c-2d, the upper leadframe portion 130ᵤ includes extensions extending inwardly into the chip region of the leadframe to accommodate the leadframe pads.

In one embodiment, an encapsulant 180 encapsulates the flip chip and leadframe. As shown, the encapsulant includes opposing top and bottom major encapsulant surfaces. In one embodiment, leadframe contacts 150_{F} are disposed on the exposed leadframe pad surfaces and chip contacts 150_{C} are disposed on exposed chip pad surfaces. In one embodiment, the leadframe contacts and chip contacts have the same volume or size to facilitate mechanical stability of the package. Other configurations of the leadframe and chip contacts may also be useful.

In one embodiment, the top encapsulant surface is coplanar with the top chip surface and top leadframe surface. This results in the top surfaces of the leadframe and chip being exposed by the encapsulant. In some cases, the top surfaces of the leadframe and chip may not be exactly coplanar or only about coplanar. However, the top surfaces are exposed by the encapsulant. In one embodiment, a heat dissipation structure 260 is disposed on the top surface of the package. For example, the heat dissipation structure is disposed on the top surfaces of the encapsulant, flip chip, and leadframe.

The heat dissipation structure, in one embodiment, is a bonded heat dissipation structure. For example, the bonded heat dissipation structure is a heat dissipating sheet having planar top and bottom heat dissipation structure surfaces. The heat dissipation structure, for example, may be made of a thermally conductive material, such as a metal, such as copper, aluminum or alloys thereof. Other types of thermally conductive materials may also be useful. The thickness of the heat dissipation structure should be sufficient to dissipate the amount of heat desired. For example, the thickness of the heat dissipation structure may be about 25 to 203 um. Other thicknesses may also be useful.

The bottom heat dissipation structure surface, in one embodiment, is bonded to the top surface of the package. The heat dissipation structure may be bonded using, for example, a thermal conductive adhesive. Various types of thermal conductive adhesives may be employed. For example, the thermal conductive adhesive may be a metal based adhesive, such as a silver based adhesive. Other techniques for bonding the heat dissipation structure may also be useful. The heat dissipation structure thermally connects the flip chip to the leadframe. This enables heat from the flip chip to be dissipated to the leadframe through the heat dissipation structure. In such cases, heat from the flip chip is directly dissipated to the heat dissipation structure and to the leadframe. For example, the heat dissipation structure provides heat dissipation by conduction.

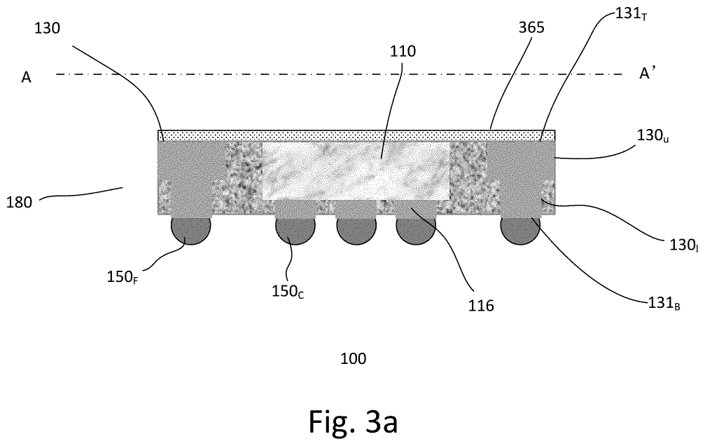

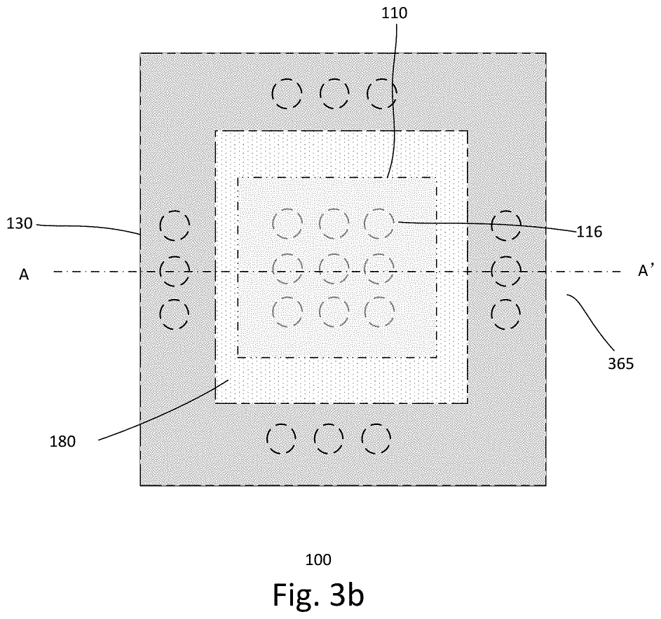

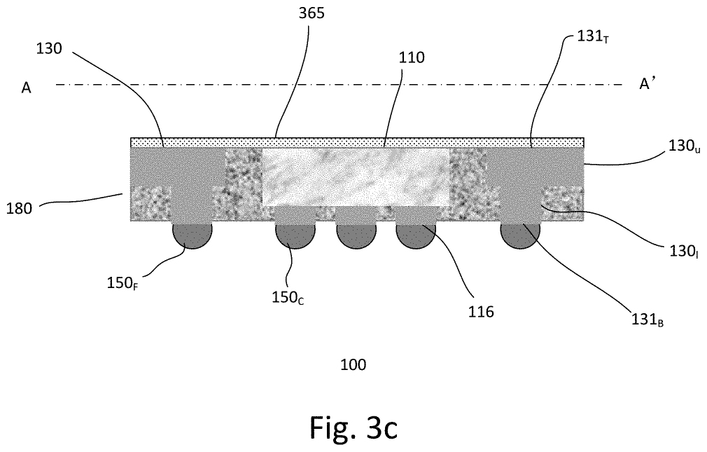

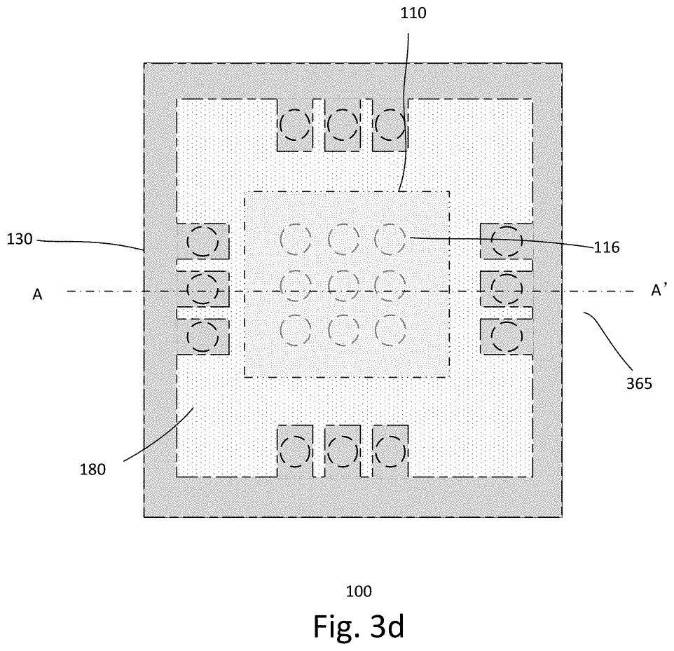

FIGS. 3a-3b show cross-sectional and top views of an embodiment of a semiconductor package 100. FIGS. 3c-3d show cross-sectional and top views of another embodiment of a semiconductor package 100. The cross-sectional views are along A-A′ of the top views. The semiconductor packages are similar to the semiconductor packages described in FIGS. 1a-1d and 2a-2d. As such, common elements may not be described or described in detail.

As shown, the semiconductor package includes a planar top package surface which includes the top surface of the encapsulant 180, the top surface of the flip chip 110 and the top surface of the leadframe 130. In one embodiment, a deposited heat dissipation structure 365 is disposed on the top package surface. The deposited heat dissipation structure, for example, includes a thermally conductive material deposited on the top package surface using, for example, various deposition processes, such as sputtering, plating or chemical vapor deposition. For example, the heat dissipation structure is a sputtered, plated vapor deposited heat dissipation structure. Other types of deposited heat dissipation structures may also be useful. In such cases, heat from the flip chip is directly dissipated to the heat dissipation structure The thickness range of the heat dissipation structure may be about 2.5-15 um. Other thicknesses for the heat dissipation structure may also be useful.

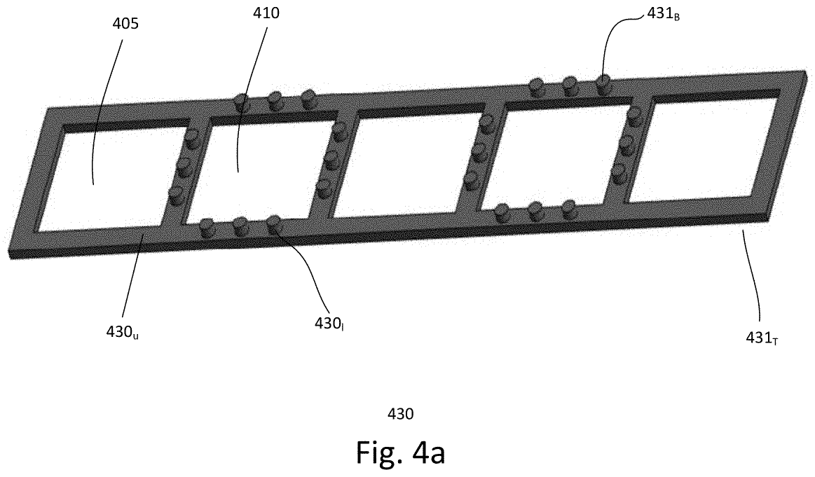

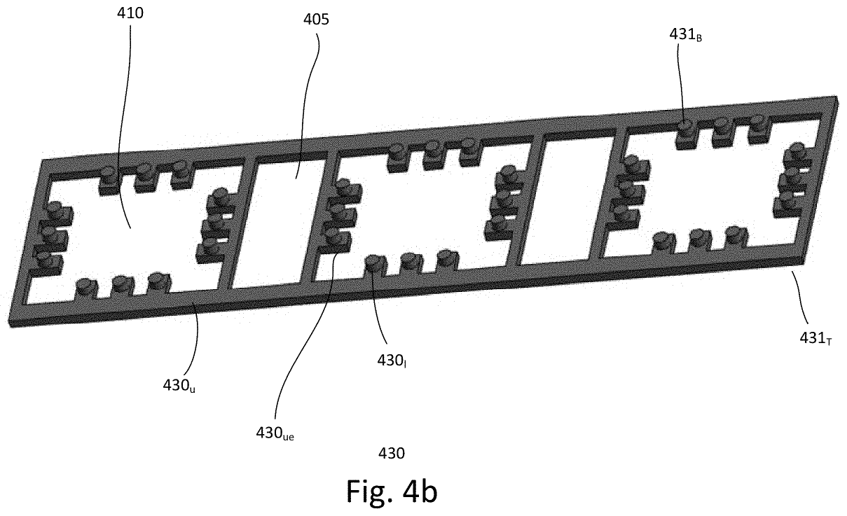

FIG. 4a shows an embodiment of a leadframe strip 430 used in forming a semiconductor package. As shown, the leadframe strip is configured to accommodate 1×X packages. For example, the leadframe is configured as a 1-dimensional matrix. Providing other configurations of the leadframe strip may also be useful. For example, the leadframe strip may be configured to accommodate Y×X packages, such as a 2-dimensional matrix with rows and columns.

The leadframe strip, in one embodiment, is a conductive leadframe. Preferably, the leadframe is a thermal conductive leadframe. For example, the leadframe is formed of a thermally conductive material, such as a copper (Cu) or copper alloy leadframe. Other types of conductive or thermally conductive materials, such as aluminum (Al), nickel (Ni), silver (Ag), gold (Au), alloys thereof, may also be used to form the lead frame.

In one embodiment, the leadframe strip is configured with a row of chip regions 410. The chip regions are configured for occupying flip chips. For example, a flip chip is disposed within a chip region. As shown, the leadframe strip is configured with alternating chip regions 410 and non-chip regions 405. Non-chip regions are regions of the leadframe not configured for accommodating flip chips. As shown, the chip regions and non-chip regions are same-sized regions. Providing chip and non-chip regions which are not the same size may also be useful. For example, the non-chip regions may be smaller than the chip regions. Other configurations of chip and non-chip regions may also be useful.

In one embodiment, the leadframe strip includes an upper leadframe portion strip 430ᵤ and a lower leadframe strip portion 430ₗ. A top surface of the upper leadframe strip portion forms a top leadframe strip surface 431_{T} and a bottom surface of the lower leadframe strip portion forms a bottom leadframe strip surface 431_{B}. In one embodiment, the upper leadframe strip portion is configured to form ring structures defining the chip regions and non-chip regions. In one embodiment, the ring structures are rectangular-shaped ring structures surrounding the chip and non-chip regions. In one embodiment, the ring structures are continuous ring structures, such as continuous rectangular-shaped ring structures. Providing non-continuous ring structures may also be useful. As for the lower leadframe strip portion, it includes leadframe pads. The leadframe pads are, for example, distinct posts extending from the ring structures. In one embodiment, the leadframe pads have a bottom surface area which is the same as the flip chip pads. In one embodiment, the leadframe pads are provided to surround the chip regions and not the non-chip regions. Other configurations of the leadframe pads may also be useful.

The leadframe strip, for example, may be formed by stamping. For example, a leadframe sheet may be stamped to form the chip and non-chip regions as well as the leadframe pads. Other techniques for forming the leadframe strip, such as etching, may also be useful.

FIG. 4b shows another embodiment of a leadframe strip 430 used in forming a semiconductor package. The leadframe strip is similar to the leadframe strip of FIG. 4a. As such, common elements may not be described or described in detail.

As shown, the leadframe strip is configured to accommodate 1×X packages. For example, the leadframe is configured as a 1-dimensional matrix. Providing other configurations of the leadframe strip may also be useful. For example, the leadframe strip may be configured to accommodate Y×X packages, such as a 2-dimensional matrix with rows and columns.

In one embodiment, chip regions 410 and non-chip regions 405 are of different sizes. In one embodiment, the non-chip regions are smaller than the chip regions. In addition, an upper leadframe portion strip 430ₙ includes leadframe extensions 430ᵤₑ extending inwardly into the chip regions of the leadframe strip. The leadframe extensions, for example, are fingerlike extensions to accommodate leadframe pads.

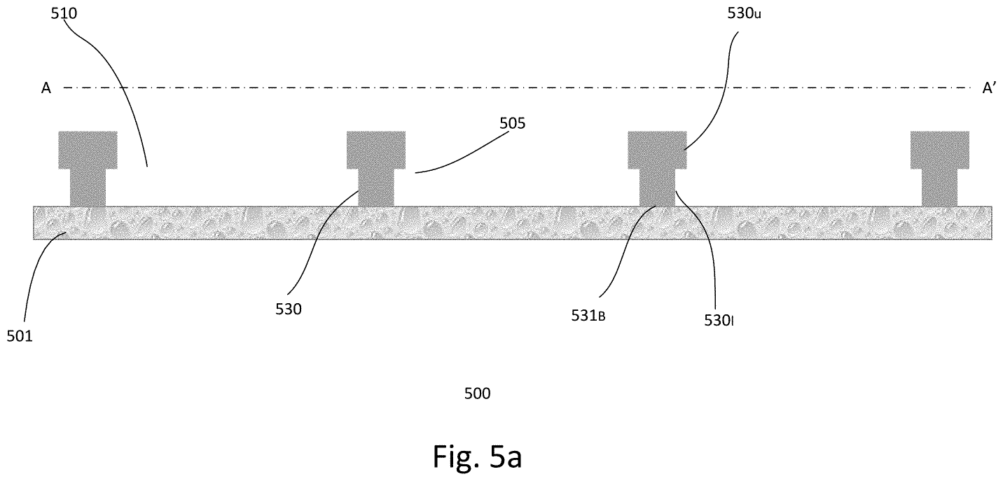

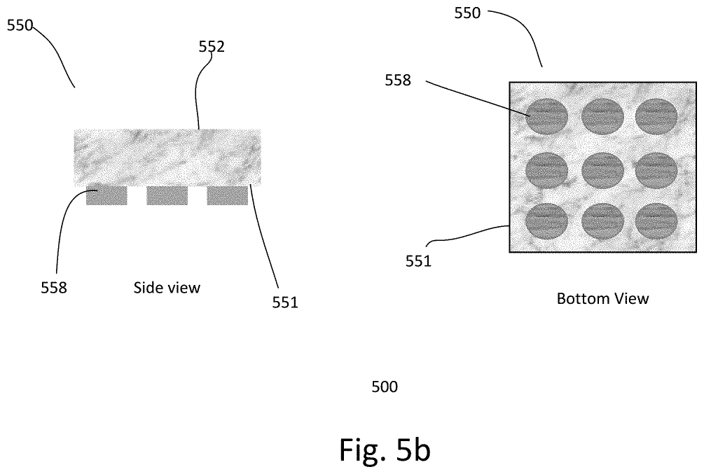

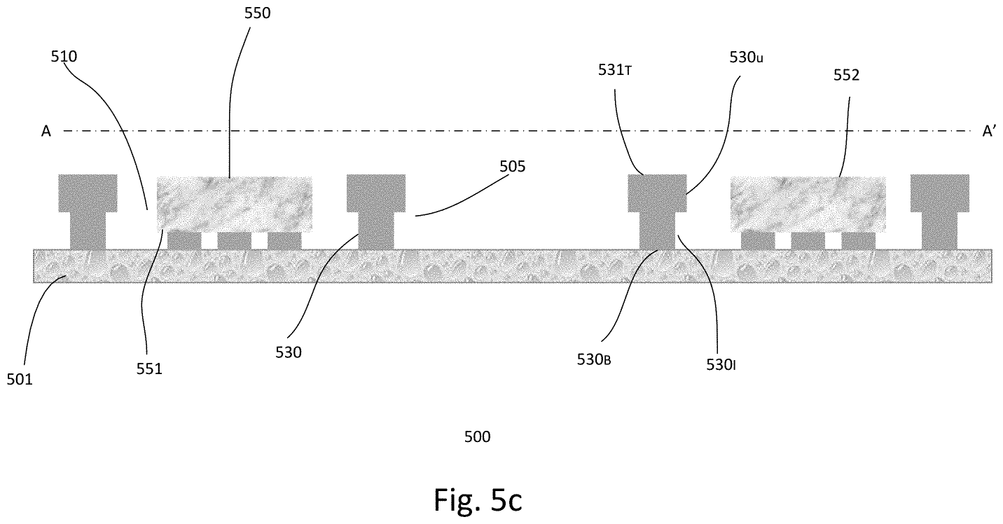

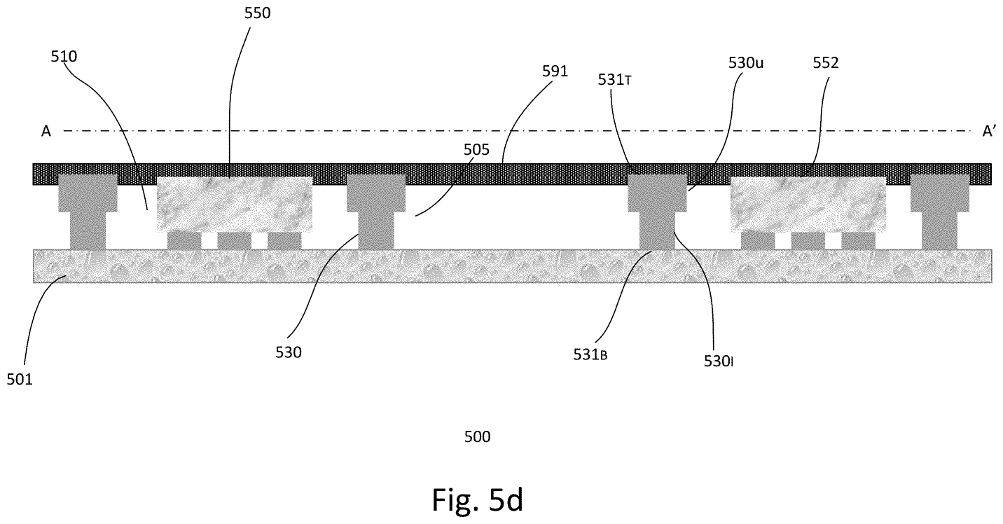

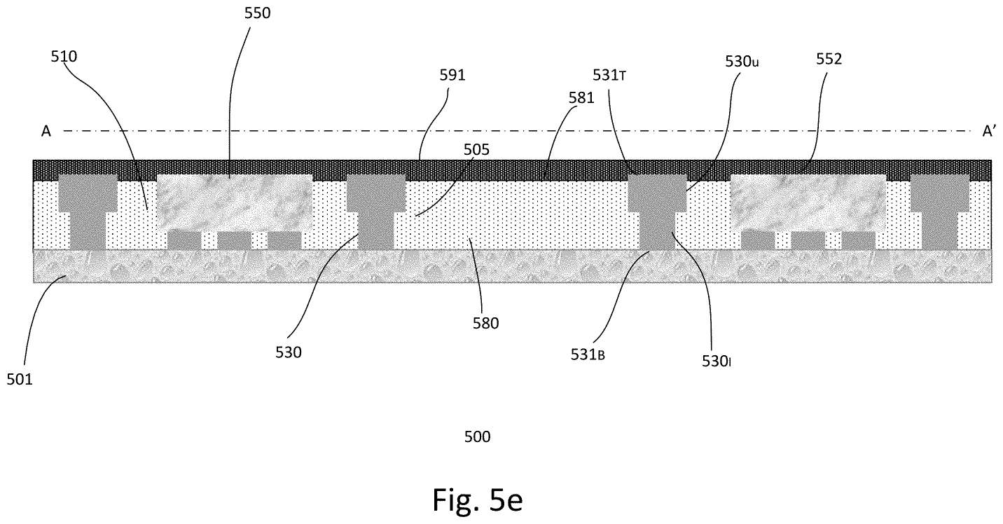

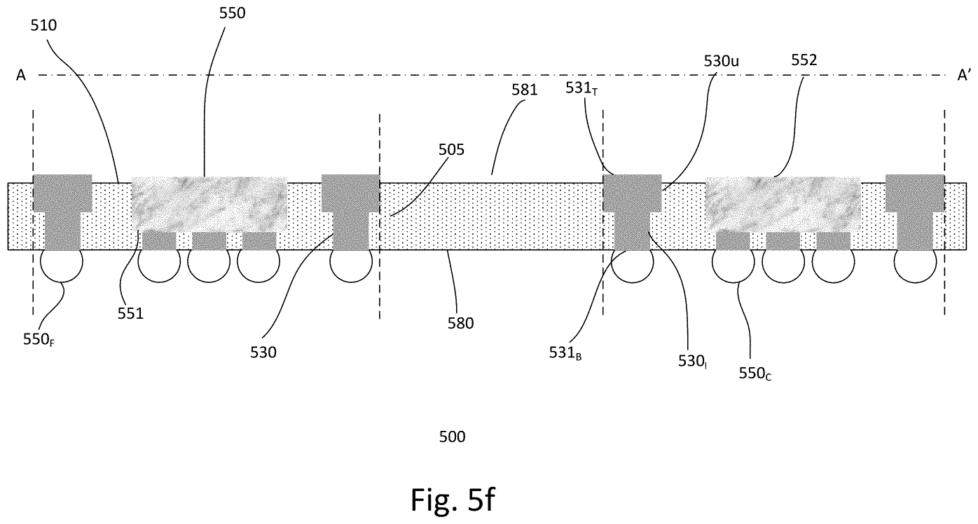

FIGS. 5a-5f show cross-sectional views of an embodiment of a process 500 for forming a semiconductor package, such as those described in FIGS. 1a-1d, 2a-2d and 3a-3d. The cross-sectional views are along A-A′. The process, as described, uses a leadframe strip as described in FIG. 4a. However, the process is applicable for the leadframe strip of FIG. 4b. Furthermore, the process may also be applicable for a leadframe of a single flip chip. Common elements may not be described or described in detail.

Referring to FIG. 5a, the process 500 begins by providing a leadframe or leadframe strip 530. As shown, the leadframe strip includes an upper leadframe strip portion 530ᵤ and a lower leadframe strip portion 530ₗ. The lower leadframe strip portion includes leadframe pads. As shown, the lead frame strip includes chip regions 510 and non-chip regions 505. A bottom lead frame surface 531_{B} is attached to a support tape 501. The support tape, for example, may be a thermal tape. Other types of tapes or films, such as Kapton® tape, may also be useful. Alternatively, the leadframe may be laminated with the support tape.

In FIG. 5b, a flip chip 550 is provided. Side and bottom views of the flip chip are shown. The flip chip includes an active surface 551 and an inactive surface 552. The active surface includes chip pads 558. The chip pads, as shown, are arranged in a grid or matrix pattern. Configuring the chip pads in other patterns may also be useful. Although the flip chip is shown with 9 chip pads, it is understood that the flip chip can have other numbers of chip pads.

As shown in FIG. 5c, flip chips 550 are bonded to the tape 501 within chip regions 510 of the leadframe strip 530. In one embodiment, the active surface 551 with the pads is bonded to the support tape. For example, a bonding tool may be employed to pick, align and bond the chips to the tape within the chip regions of the leadframe strip. As shown, a top surface 552 of the chips is about coplanar with a top leadframe strip surface 531_{T}. Other configurations of the surfaces of the chips and leadframe strip may also be useful.

In one embodiment, as shown in FIG. 5d, a tape 591 is attached to the leadframe and chips. The tape, for example, may be a molding tape and is used for a film assist molding. The molding tape, for example, is flexible and can be compressed to fill the gaps between the leadframe strip and chips. The molding tape, for example, may be a high thermal tape. Other types of tapes or films, such as Kapton® tape, may also be useful. In one embodiment, the tape may be compressed to less than 5 um below the top surfaces of the leadframe strip and chips. Compressing the tape by other amounts may also be useful.

In FIG. 5e, an encapsulant 580 is disposed on the leadframe strip. The encapsulant fills the space between the tapes, leadframe strip and chips. The encapsulant, for example, may be a mold compound. As discussed, the encapsulant is formed by, for example, film assist molding. As shown, a top surface 581 of the encapsulant is disposed below the top surfaces of the leadframe strip and chips. For example, the encapsulant is disposed less than Sum below the top surfaces of the leadframe strip and chips. Providing the top encapsulant surface below the top surfaces of the leadframe strip and chips by other amounts may also be useful. The encapsulant, leadframe strip and flip chips form a molded assembly.

Referring to FIG. 5f, the molded assembly is separated from the support and molding tapes. For example, the molding tape may be part of mold cavity. When the mold cavity is released from the molded assembly, the molding tape is removed along with the mold cavity. Removing the support tape, for example, is achieved by machine such as tape delaminator or manual operation. After tape removal, the bottom surfaces of the chip pads and leadframe pads are exposed. Leadframe contacts 550_{F} and chip contacts 550_{C} are formed on the pads. The contacts, for example, are solder ball or bump contacts. Other types of contacts may also be formed. The molding tape is removed after contact formation. The molded assembly with the contacts is singulated to form individual packages, as indicated by the dotted lines.

In other embodiments, the encapsulant may be formed by other techniques, such as transfer molding. Other techniques for forming the encapsulant may also be useful. The encapsulant may be formed having a top surface which covers the leadframe strip and chips. In the case that the top encapsulant surface is above the top surfaces of the leadframe strip and chips, the top encapsulant surface 581 may be processed to reduce it to the desired height hₑ. In one embodiment, the processed top encapsulant surface may be processed to be slightly recessed below the top surfaces of the flip chips and leadframe strip. For example, the encapsulant may be etched to have a top surface slightly below the top surfaces of the leadframe strip and flip chips, such as less than 5 um. Recessing the top encapsulant surface below the top surfaces of the leadframe strip and flip chips may also be useful.

In yet other embodiments, the top encapsulant surface may be processed to a desired height hₑ which is above the top surfaces of the leadframe strip and flip chips, such as less than 5 um. Processing the desired height hₑ above the top surfaces of the leadframe strip and flip chips by other amounts may also be useful. In other embodiments, the desired height hₑ may be coplanar with the top surfaces of the leadframe strip and flip chips. Processing the encapsulant may be achieved by grinding or etching. Other techniques for processing the encapsulant may also be useful.

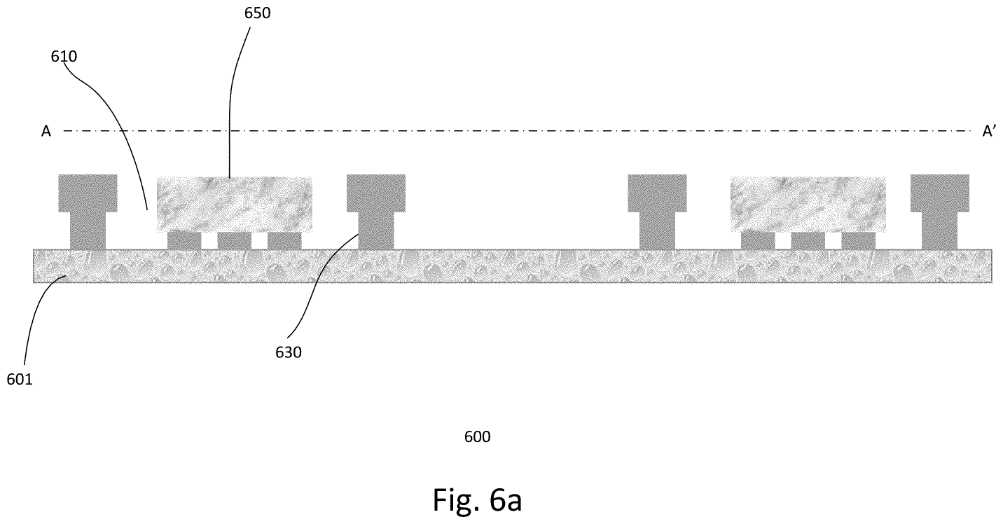

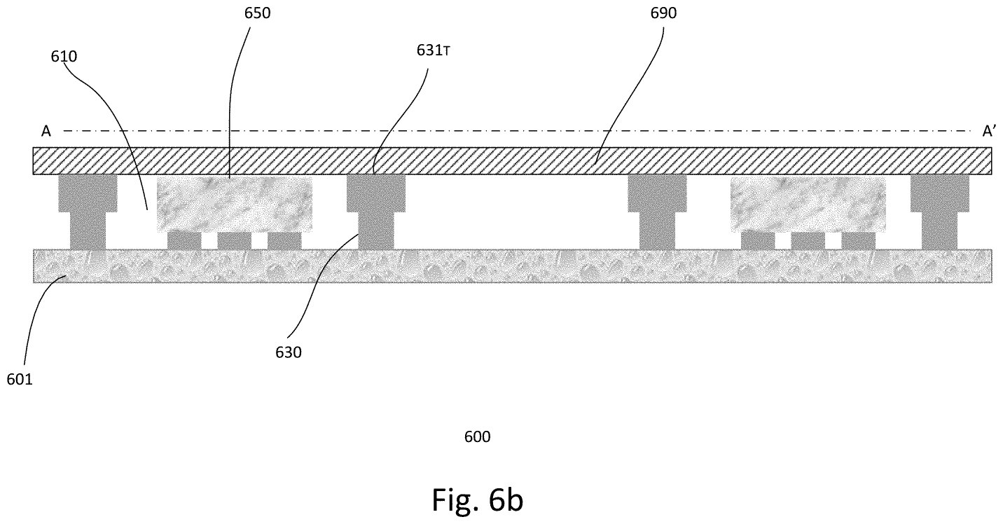

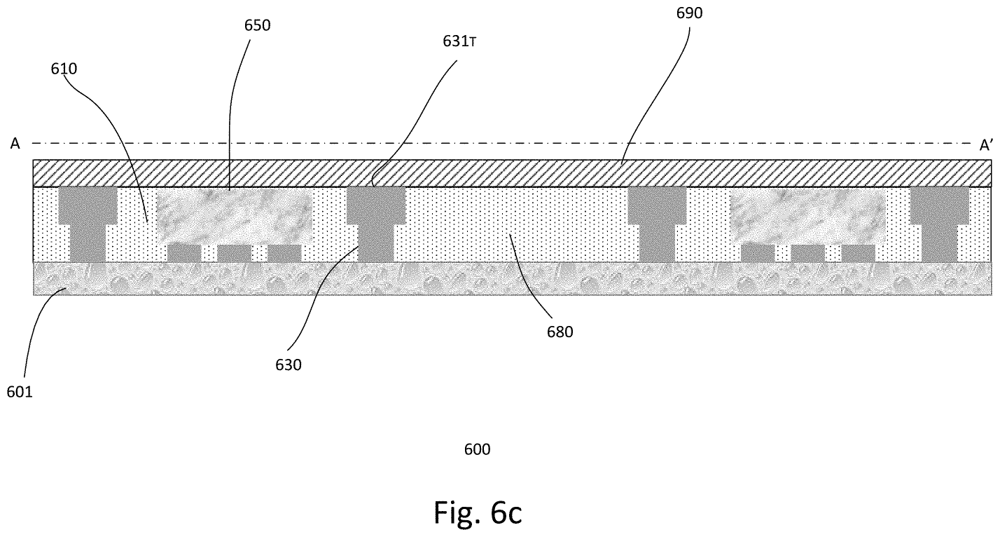

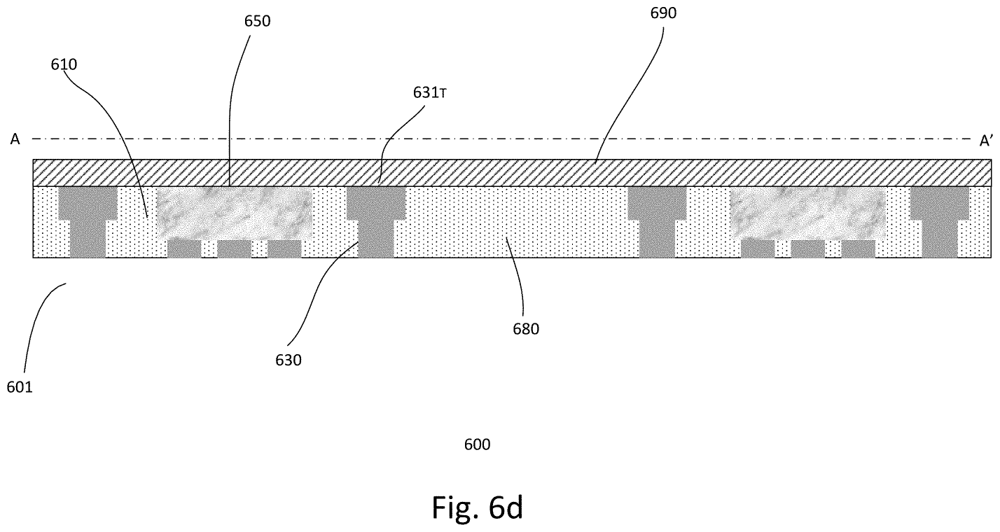

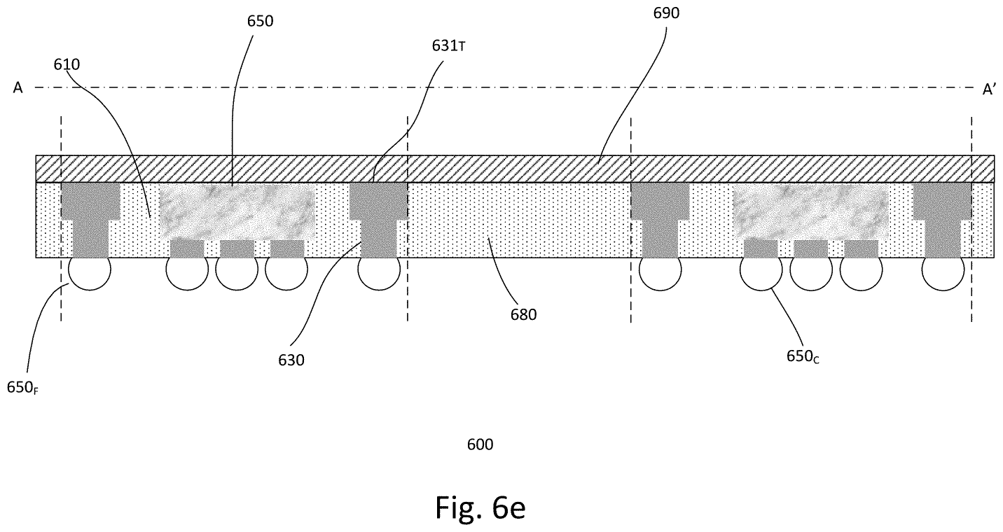

FIGS. 6a-6e show cross-sectional views of another embodiment of a process 600 for forming a semiconductor package, such as those described in FIGS. 2a-2d and 3a-3d. The cross-sectional views are along A-A′. The process, as described, is similar to that of FIGS. 5a-5f. Common elements may not be described or described in detail.

Referring to FIG. 6a, the stage of processing is similar to that described in FIG. 5c. For example, flip chips 650 are bonded to chip regions 610 of support tape 601 with a leadframe 630.

Continuing to FIG. 6b, a heat dissipation structure 690 is attached to the top lead frame surface 631_{T} and top surface of the flip chips. In one embodiment, the heat dissipation structure is bonded to the leadframe and flip chips using a thermal conductive adhesive. The bonded heat dissipation structure provides thermal conduction to dissipate heat from the flip chips during operation to the leadframe. Alternatively, the heat dissipation structure may be provided at unit level. For example, the heat dissipation structure may be bonded to the top package surface after singulation.

In FIG. 6c, an encapsulant 680 is disposed on the leadframe strip. The encapsulant covers the leadframe strip and flip chips. The encapsulant, for example, fills the spaces between the support tape and bonded thermal dissipation structure. The encapsulant may be formed by, for example, transfer molding or compression molding. Other techniques for forming the encapsulant may also be useful. The encapsulant, the flip chips, and the leadframe form a molded assembly.

Referring to FIG. 6d, the molded assembly is separated from the support tape. Removing the support tape, for example, is achieved by machine such as tape delaminator or manual operation. After tape removal, the bottom surfaces of the chip pads and leadframe pads are exposed.

In FIG. 6e, leadframe contacts 650_{F} and chip contacts 650c are formed on the pads. The contacts, for example, are solder ball or bump contacts. Other types of contacts may also be formed. The molded assembly with the contacts is singulated to form individual packages, as indicated by the dotted lines.

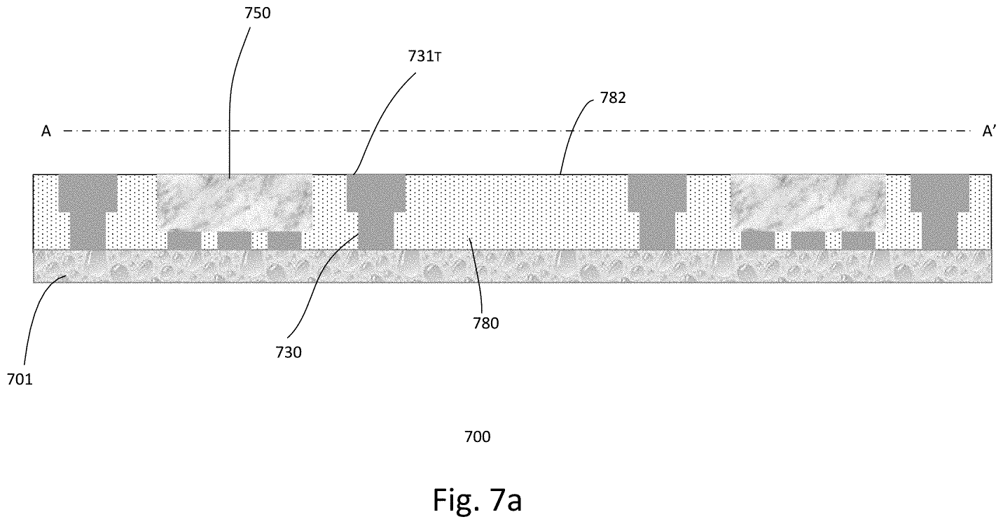

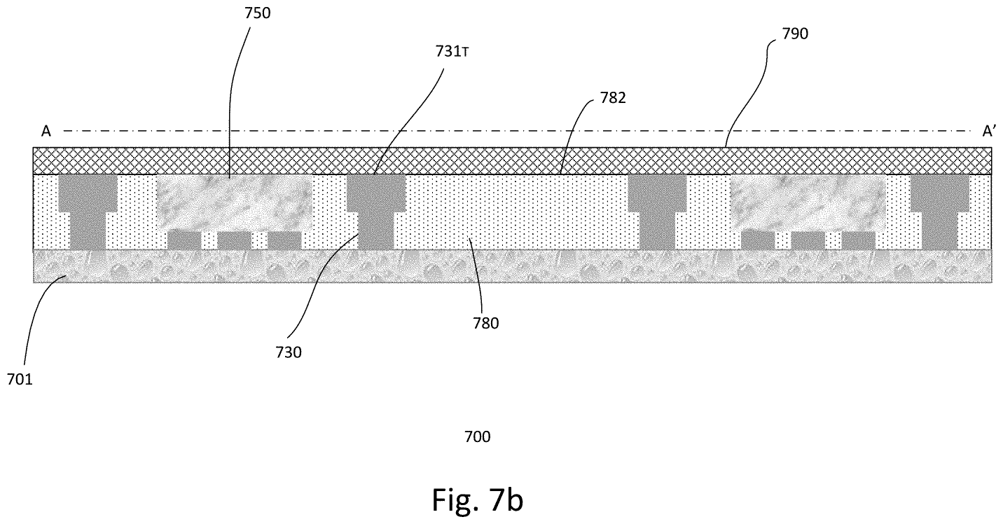

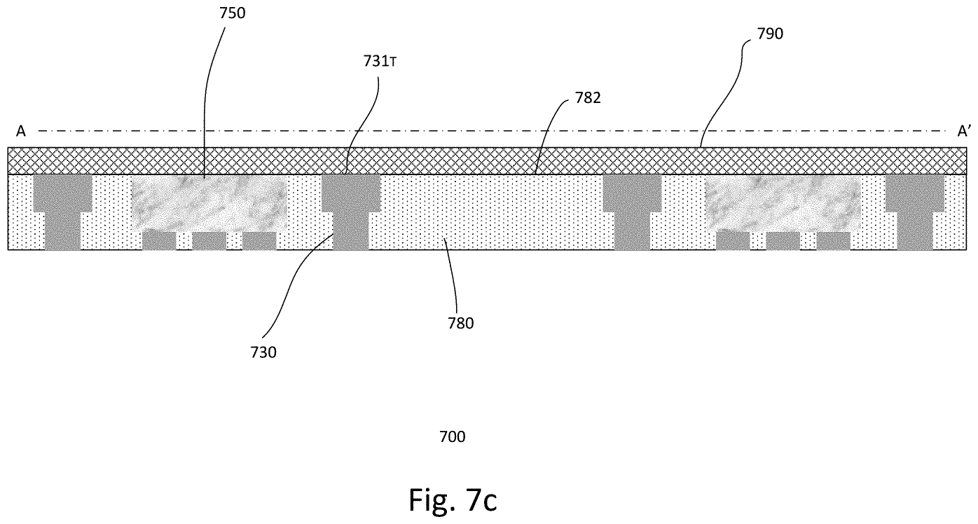

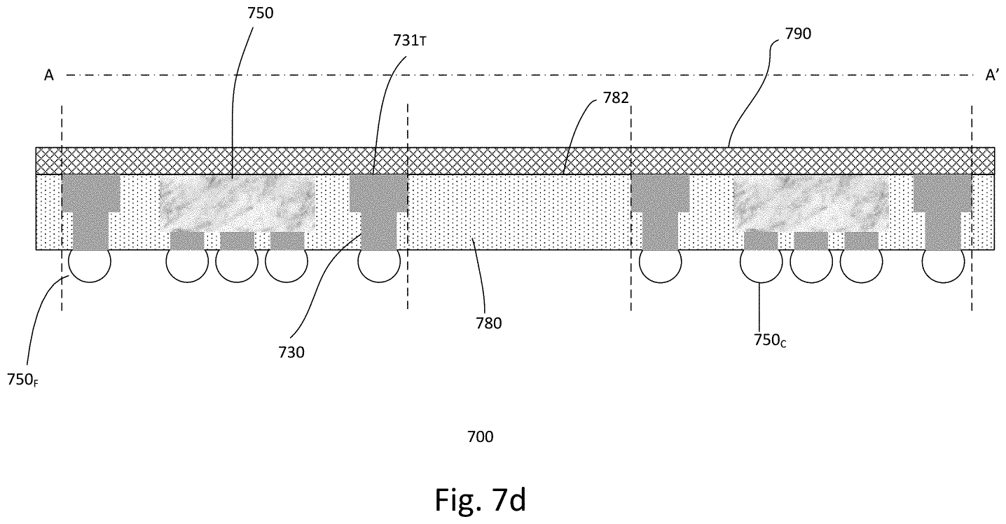

FIGS. 7a-7d show cross-sectional views of another embodiment of a process 700 for forming a semiconductor package, such as those described in FIGS. 2a-2d and 3a-3d. The cross-sectional views are along A-A′. The process, as described, is similar to that of FIGS. 5a-5f and 6a-6e. Common elements may not be described or described in detail.

Referring to FIG. 7a, the stage of processing is similar to that described in FIG. 5e. For example, a molded assembly is formed on the support tape 701. The molded assembly includes an encapsulant 780 filling the spaces between the leadframe 730 and flip chips 750. In one embodiment, a top encapsulant surface 782 is coplanar with a top leadframe surface 731_{T} and top surfaces of the flip chips.

In FIG. 7b, a heat dissipation structure 790 is disposed onto the molded assembly. For example, the heat dissipation structure contacts the top surfaces of the flip chips and the top lead frame surface 731_{T}. In one embodiment, the heat dissipation structure is a bonded heat dissipation structure. For example, a heat dissipating sheet is bonded to the top of the molded assembly using a thermal conductive adhesive. In another embodiment, the heat dissipation structure is a deposited heat dissipation structure. For example, heat dissipation structure material is deposited on top of the molded assembly. Various deposition techniques may be employed. For example, the deposited heat dissipation structure may be formed by sputtering, plating or chemical vapor deposition. Other deposition techniques to form the deposited heat dissipation structure may also be useful. The heat dissipation structure provides thermal conduction to dissipate heat from the flip chips during operation to the leadframe. Alternatively, the heat dissipation structure may be provided at unit level. In one embodiment, the bonded heat dissipation structure is bonded to the top package surface after singulation. In another embodiment, the deposited heat dissipation structure is deposited on the top package surface after singulation.

Referring to FIG. 7c, the molded assembly with the heat dissipation structure is separated from the support tape. Removing the support tape, for example, is achieved by machine such as tape delaminator or manual operation. After tape removal, the bottom surfaces of the chip pads and leadframe pads are exposed.

As shown in FIG. 7d, leadframe contacts 750_{F} and chip contacts 750_{C} are formed on the pads. The contacts, for example, are solder ball or bump contacts. Other types of contacts may also be formed. The molded assembly with the contacts is singulated to form individual packages, as indicated by the dotted lines.

The present disclosure may be embodied in other specific forms without departing from the spirit or essential characteristics thereof. The foregoing embodiments, therefore, are to be considered in all respects illustrative rather than limiting the invention described herein. Scope of the invention is thus indicated by the appended claims, rather than by the foregoing description, and all changes that come within the meaning and range of equivalency of the claims are intended to be embraced therein.

What is claimed is:

1. A semiconductor package comprising:
a flip chip having opposing active and inactive chip surfaces, wherein the active chip surface includes chip pads;
a leadframe surrounding the flip chip, the leadframe includes top and bottom leadframe surfaces, wherein the bottom leadframe surface includes leadframe pads;
an encapsulant having opposing top and bottom encapsulant surfaces, the encapsulant encapsulating the leadframe and the flip chip, wherein the bottom encapsulant surface exposes the leadframe pads and chip pads;
leadframe contacts coupled to the leadframe pads;
chip contacts coupled to the chip pads; and
wherein the leadframe contacts and chip contacts protrude from the bottom mold compound surface and form package contacts of the semiconductor package.

2. The semiconductor package of claim 1, wherein the top encapsulant surface is disposed below the top leadframe surface and the inactive chip surface.

3. The semiconductor package of claim 2, wherein the top encapsulant surface is disposed below the top leadframe surface and the inactive chip surface by less than about 5 um.

4. The semiconductor package of claim 1, wherein the top leadframe surface and the inactive chip surface are about coplanar.

5. The semiconductor package of claim 1, wherein the top leadframe surface and the inactive chip surface are exposed by the top encapsulant surface.

6. The semiconductor package of claim 6, wherein the top encapsulant surface, the top leadframe surface and the inactive chip surface are coplanar.

7. The semiconductor package of claim 5 comprises a heat dissipation structure, the heat dissipation structure is thermally connected to the inactive chip surface and top leadframe surface.

8. The semiconductor package of claim 7, wherein the heat dissipation structure comprises a bonded heat dissipation structure.

9. The semiconductor package of claim 8 comprises a thermal conductive adhesive, the thermal conductive adhesive bonds the heat dissipation structure to the top lead frame surface, the top encapsulant surface and inactive chip surface with a thermal conductive adhesive.

10. The semiconductor package of claim 7, wherein the heat dissipation structure comprises a deposited heat dissipation structure.

11. The semiconductor package of claim 1, wherein the leadframe contacts are not electrically connected to the flip chip.

12. The semiconductor package of claim 1 wherein the leadframe comprises:
an upper leadframe portion which includes the top leadframe surface, the upper includes a ring leadframe structure surrounding the flip chip; and
a lower leadframe which includes the leadframe pads.

13. The semiconductor package of claim 12 wherein:
side encapsulant surfaces of the encapsulant are aligned with side leadframe surfaces of the upper leadframe portion; and
side encapsulant surfaces cover the leadframe pad sides of the leadframe pads of the lower leadframe portion.

14. The semiconductor package of claim 1 wherein the leadframe comprises:
an upper leadframe portion which includes the top leadframe surface, the upper includes a ring leadframe structure surrounding the flip chip;
leadframe fingers extending from the ring leadframe structure inwards towards the flip chip; and
a lower leadframe which includes the leadframe pads on the leadframe fingers.

15. The semiconductor package of claim 14 wherein:
side encapsulant surfaces of the encapsulant are aligned with side leadframe surfaces of the upper leadframe portion; and
side encapsulant surfaces cover the leadframe pad sides of the leadframe pads of the lower leadframe portion.

16. A method for forming a semiconductor package comprising:
providing a leadframe with top and bottom leadframe surfaces, wherein the bottom leadframe surface includes leadframe pads;
attaching the bottom leadframe surface to a support adhesive tape;
providing a flip chip having opposing active and inactive chip surfaces, wherein the active chip surface includes chip pads;
attaching the chip pads of the flip chip to the support adhesive tape within a chip region in a central portion of the leadframe;
encapsulating the leadframe with the flip chip with an encapsulant;
removing the support tape to expose bottom leadframe pad surfaces of the leadframe pads and bottom chip pad surfaces of the chip pads; and
forming leadframe contacts on the bottom leadframe pad surfaces and chip contacts on the bottom chip pad surfaces.

17. A method for forming a semiconductor package comprising:
providing a leadframe strip with a plurality of leadframes, the leadframe strip includes top and bottom leadframe strip surfaces, wherein the bottom leadframe strip surface includes leadframe pads of the plurality of leadframes;
attaching the bottom leadframe strip surface to a support adhesive tape;
providing flip chips having opposing active and inactive chip surfaces, wherein the active chip surface of the flip chips includes chip pads;
attaching the chip pads of the plurality of flip chips to the support adhesive tape within chip regions of the leadframes, wherein a chip region of a leadframe is a central portion of the leadframe;
encapsulating the leadframe strip with the flip chips with an encapsulant;
removing the support tape to expose bottom leadframe pad surfaces of the leadframe pads and bottom chip pad surfaces of the chip pads;
forming leadframe contacts on the bottom leadframe pad surfaces and chip contacts on the bottom chip pad surfaces; and
singulating the leadframe strip into individual packages.
